(19) United States
(12) Patent Application Publication
(10) Pub. No.: US 2023/0031266 A1
(43) Pub. Date: Feb. 2, 2023

(54) METHODS AND APPARATUSES INVOLVING DIAMOND GROWTH ON GAN

(71) Applicants: The Regents of the University of California, Stanford (US); The Board of Trustrees of the Leland Stanford Junior University, Stanford (US)

(72) Inventors: Srabanti Chowdhury, San Ramon, CA (US); Mohamadali Malakoutian, Davis, CA (US); Matthew A. Laurent, Rancho Palos Verdes, CA (US); Chenhao Ren, Davis, CA (US); Siwei Li, Davis, CA (US)

(21) Appl. No.: 17/790,675

(22) PCT Filed: Jan. 8, 2021
(86) PCT No.: PCT/US2021/012619

§ 371 Date: Jul. 1, 2022

Related U.S. Application Data
(60) Provisional application No. 62/958,584, filed on Jan. 8, 2020.

(51) Int. Cl. H01L 29/267; H01L 21/02; H01L 27/06; H01L 27/12; H01L 27/088

(52) U.S. Cl. CPC H01L 29/267; H01L 21/02458; H01L 27/0605; H01L 27/0617; H01L 27/1203; H01L 27/088; H01L 21/02527; H01L 21/02595; H01L 29/1602

(57) ABSTRACT

In certain examples, methods and semiconductor structures are directed to a method comprising steps of forming by monolithically integrating or seeding via polycrystalline diamond (PCD) particles on a GaN-based layer characterized as including GaN in at least a surface region of the GaN-based layer. After the step of seeding, the PCD particles are grown under a selected pressure to form a diamond layer section and to provide a semi-conductive structure that includes the diamond layer section integrated on or against the surface region of the GaN-based layer.

### FEDERALLY-SPONSORED RESEARCH AND DEVELOPMENT

This invention was made with Government support under contract D15AP00092 awarded by the Defense Advanced Research Projects Agency. The Government has certain rights in the invention.

### BACKGROUND

Exemplary aspects of the instant disclosure are related generally to the field of semiconductor devices and in some instance may be applicable to and/or used in connection with high power and/or high frequency devices. As discussed further herein, certain aspects of the disclosure are directed to a heterogeneous integration of diamond and GaN-based field effect transistors (FETs), as may be applied to realize high density and high mobility holes and electrons.

High-electron mobility transistors (or HEMTs) such as GaN-based FETs have exhibited an extremely high-power output at high frequencies. However, there are some significant limiting factors of the performance in GaN HEMTs, and this may lead to a reduced channel mobility and large leakage current due to the semiconductor devices, in which the transistors are formed, self-heating. Therefore, it may be beneficial to dissipate the generated heat from such devices. Owing to the excellent heat conductivity of certain materials such as diamond which is about 20 W/cm·K, previous efforts have attempted to use such materials to spread the heat from the top of the device. However, in connection with such efforts involving GaN-based FETs, problems have been encountered. For example, in attempting to use a diamond to dissipate the heat from a GaN-based device, it is important to couple the diamond right up against the GaN layer, but such growth can prevent a uniform PCD deposition on the surface, as the hydrogen plasma is etching at the same time.

Also, previous efforts which have used a layer of polycrystalline diamond grown on the GaN layer to spread the heat from the top of the device, due to hydrogen plasma being the main species in diamond growth, the growth process damages the GaN material and thereby changes the properties of the 2-dimensional electron gas (2DEG) associated with operation of such transistors. Changing the 2DEG properties is undesirable, because these properties largely control the switching speeds of the transistors. For example, in certain uses of a HEMT, to turn off a normally-On GaN-based FET, the 2DEG (2 dimensional electron gas) layer is depleted, to permit a negative voltage to be applied between the gate and source of the FET. As in certain known GaN-based FETs, electrons concentrated in a 2DEG layer under the gate may depleted in this regard so that current through the FET's underlying GaN layer is effectively blocked.

Accordingly, there continue to be issues and areas for improving semi-conductive structures that include heat-distributing layers in fast-switching devices such as GaN-based FETs.

### SUMMARY OF VARIOUS ASPECTS AND EXAMPLES

Various examples/embodiments presented by the present disclosure are directed to issues such as those addressed above and/or others which may become apparent from the following disclosure. For example, some of these disclosed aspects are directed to methods and devices that use or leverage from the benefits of a diamond-based layer used to distribute heat in fast-switching devices such as GaN-based HEMTs (high-electron mobility transistors). Among many other aspects disclosed herein, certain examples are directed to overcoming problems encountered in connection with previous attempts to develop effective fast-switching devices.

In one specific example, a method and/or a semiconductor device involves polycrystalline diamond (PCD) particles on a GaN-based layer. One example method is directed to steps of forming by monolithically integrating for example by seeding via use of PCD particles on a GaN-based layer (or substrate) with the GaN-based layer characterized as including GaN in at least a surface region of the GaN-based layer, or throughout the layer. After the step of forming, the PCD particles are grown under a selected pressure to form a diamond layer section and to provide a semi-conductive structure that includes the diamond layer section integrated on or against the surface region of the GaN-based layer.

In certain other examples which may also build on the above-discussed aspects, methods and semiconductor structures are directed to the growth aspects with the pressure being selected to set a desired grain size which in turn is associated with sp² and hydrogen content in the diamond layer section.

Another specific example involves a semi-conductive structure including a GaN-based layer including GaN in at least a surface region of the GaN-based layer, and a diamond layer section which is integrated on or against the surface region of the GaN-based layer. The diamond layer section is characterized as having been grown for example by seeding with polycrystalline diamond (PCD) particles.

In such a structure, it is apparent for example that the GaN-based layer does not manifest etching damage, and/or the properties of 2-dimensional electron gas (2DEG) being maintained during operation.

The above discussion is not intended to describe each aspect, embodiment or every implementation of the present disclosure. The figures and detailed description that follow also exemplify various embodiments.

### BRIEF DESCRIPTION OF FIGURES

Various example embodiments, including experimental examples, may be more completely understood in consideration of the following detailed description in connection with the accompanying drawings, each in accordance with the present disclosure, in which:

FIG. 1 is diagram illustrating formation of a structure, for example, by seeding and growing PCD particles on an example GaN-based layer while under pressure, according to certain exemplary aspects of the present disclosure;

FIG. 2 is cross section diagram illustrating example diamond-on-GaN architectures, according to certain exemplary aspects of the present disclosure;

FIG. 3A is a top view illustrating an example polycrystalline diamond grown on top of GaN, according to certain exemplary aspects of the present disclosure;

FIG. 3B is a cross-sectional view illustrating an example polycrystalline diamond grown on top of GaN, according to certain exemplary aspects of the present disclosure;

FIG. 4 is a Raman spectra graph and top view micrographs illustrating an example diamond-on-GaN growth method implemented at various pressures, according to certain exemplary aspects of the present disclosure;

FIG. 5A is a circuit diagram illustrating an example CFET or CMOS inverter, according to certain exemplary aspects of the present disclosure;

FIG. 5B is a graph illustrating the voltage transfer characteristics of an example complementary transistor based inverter according to certain exemplary aspects of the present disclosure;

FIG. 6A is a graph illustrating the I_{D} versus V_{DS} characteristics of an example FET (e.g., metal-semiconductor field-effect transistor type or MESFET) according to certain exemplary aspects of the present disclosure;

FIG. 6B is a graph illustrating the transconductance (gₘ) versus gate bias (V_{GS}) characteristics of an example MESFET according to certain exemplary aspects of the present disclosure;

FIG. 6C is a graph illustrating I_{D} versus gate bias (V_{GS}) characteristics of an example MESFET according to certain exemplary aspects of the present disclosure; and

FIG. 6D is a graph illustrating I_{D} versus V_{DS} characteristics and the breakdown field of an example MESFET according to certain exemplary aspects of the present disclosure.

While various embodiments discussed herein are amenable to modifications and alternative forms, aspects thereof have been shown by way of example in the drawings and will be described in detail. It should be understood, however, that the intention is not to limit the disclosure to the particular embodiments described. On the contrary, the intention is to cover all modifications, equivalents, and alternatives falling within the scope of the disclosure including aspects defined in the claims. In addition, the term “example” as used throughout this application is only by way of illustration, and not limitation.

### DETAILED DESCRIPTION

Exemplary aspects of the present disclosure are applicable to a variety of different types of apparatuses, systems and methods involving for example HEMT-type devices such as GaN-based FETs having a GaN-based layer and a diamond layer section, integrated on or against the surface region of the GaN-based layer. While the present disclosure is not necessarily limited to such aspects, an understanding of specific examples in the following description may be understood from discussion in such specific contexts.

Accordingly, in the following description various specific details are set forth to describe specific examples presented herein. It should be apparent to one skilled in the art, however, that one or more other examples and/or variations of these examples may be practiced without all the specific details given below. In other instances, well known features have not been described in detail so as not to obscure the description of the examples herein. For ease of illustration, the same connotation and/or reference numerals may be used in different diagrams to refer to the same elements or additional instances of the same element. Also, although aspects and features may in some cases be described in individual figures, it will be appreciated that features from one figure or embodiment can be combined with features of another figure or embodiment even though the combination is not explicitly shown or explicitly described as a combination.

Consistent with the above aspects, such a manufactured device or method of such manufacture may involve aspects presented and claimed in U.S. Provisional Patent Application Ser. No. 62/958,584 filed on Jan. 8, 2020 (STFD.418P1), to which priority is claimed. To the extent permitted, such subject matter is incorporated by reference in its entirety generally and to the extent that further aspects and examples (such as experimental and/more-detailed embodiments) may be useful to supplement and/or clarify.

Consistent with the present disclosure, such devices and/or methods may be used for producing (among other examples disclosed herein) HEMT, MESFET, CFET (e.g., complementary-type FET such as a complementary-metal-oxide-semiconductor or CMOS) type transistor or inverter. Exemplary aspects of the present disclosure are related to semi-conducting structures constructed by monolithically integrating or seeding a GaN-based layer with polycrystalline diamond (PCD) particles and then grown under a selected pressure to form a diamond layer section.

As noted above, certain exemplary aspects of the present disclosure involve methodology and structures directed to monolithically integrating or seeding a GaN-based layer with polycrystalline diamond (PCD) particles. The GaN layer being characterized as including GaN in, at least, a surface region of the layer. The PCD particles may be grown under a selected pressure to form a diamond layer section. This provides a semi-conductive structure that includes the diamond layer section integrated on, or against, the surface region of the GaN-based layer.

According to certain more specific examples, the present disclosure is directed to a method and alternatively, a device manufactured from the method involving a semi-conductive structure or device having a grain size associated with sp² and hydrogen content in the diamond layer section. This grain size may be selected by control of the pressure used in the process of growing the PCD particles after they have been seeded.

Further aspects, according to the present disclosure, are directed to a method of growing these PCD particles under a selected pressure. Using this method of pressure to assist, forming the diamond layer with a desired particle size may be accomplished without the use of chemical vapor deposition.

Yet further aspects, according to the present disclosure, are directed to a method involving a semi-conductive structure that is, or includes, a GaN based FET. This structure may also include a diamond layer section on, or against, the GaN-based layer. This diamond layer may be beneficial for spreading heat generated while operating the FET.

In other specific embodiments, the present disclosure presents a method of using oxygen termination of the surface of the diamond layer section, described previously, after it is grown as required.

In yet another example, the method may include creating a semi-conductive structure of a MESFET (metal-semiconductor field-effect transistor), or a semi-conductive structure that includes a MESFET.

According to specific examples of the present disclosure, embodiments are directed to or involve creating a semi-conductive structure of a HEMT (high-electron-mobility transistor), or a semi-conductive structure that includes a HEMT.

In one specific example, examples are directed to a method involving seeding a surface with PCD particles, as described previously, which may provide an activation region for growing the PCD particles.

In another specific example, embodiments are directed to a method including etching. When using etching in the process, the PCD particles may provide etching protection to the GaN-based layer.

Consistent with the above aspects and in yet other detailed examples, another important aspect of the instant disclosure involves a method of seeding the surface region of a GaN-based layer by directly locating PCD particles on the GaN layer.

In certain non-limiting experimental-test embodiments, the above-described approaches for diamond-on-GaN construction has realized impressive results. One such system embodiment has been tested successfully and it has been discovered (in experimental or proof-of-concept efforts) that by increasing the pressure from 40 to 60 torr, there is a slight change in the grain size (130 to 180 nm), while at 80 torr the grain size increases by a factor of ˜2 from 60 torr case (180 to 350 nm). PCD with 130, 180, or 350 nm grain size corresponds to a thermal conductivity of 40, 58, or 110 W/m·K, respectively. From the cross-sectional view of SEM micrographs, it can be seen that the thickness and the growth rate of the PCD are increasing by elevating the pressure (or the plasma density). The PCD thickness is ˜170 nm for 40 torr, ˜250 nm for 60 torr, and ˜400 nm for 80 torr pressure.

The grain size determines the surface to volume ratio, which corresponds to the sp² and hydrogen content. So, to have more sp³ bonding less grain boundaries or larger grain sizes are desired. It can be clearly seen that, by increasing the pressure the Raman spectra exhibits a reasonably sharper diamond peak around 1332 cm⁻¹, which confirms lower surface to volume ratio and higher sp³ bonding. In the Raman spectra, there is also some signs of sp² bonding and the hydrogen from the grain boundaries at around 1120, 1450, and 1560 cm⁻¹, which changes slightly with pressure. According to certain experimental results associated with particular embodiments, the larger grain size of the PCD is desired for heat spreading purposes, as the thermal conductivity increases by the grain size. To have a larger grain size and higher sp³ bonding ratio, a higher growth pressure is found to be beneficial or needed.

Certain experimental efforts consistent with the above-disclosed aspects and embodiments were directed to the following specific example aspects. The PCD particles are characterized as having a grain size that is within a range from 650 nanometers a lower grain size to an upper grain size as high as 2.5 microns in certain example and as high as several microns in other examples. In one or more of these experiments, the growth facilitated the monolithic integration of the semi-conductive structure and a structure including the GaN-based layer (e.g., resulting in a remarkably smooth surface).

In more specific experiments consistent with the above-noted one or more of these experiments (wherein the polycrystalline diamond (PCD) particles having a grain size that is within such ranges), the method further including controlling the growth via certain growth-environment parameters used during the growing process, and these growth parameters include growth under pressure (e.g., 40 torr or in a range from 30 to 70 torr), high-temperature (e.g., 450° C. plus or minus 10-35%), and at least one cooling stage after such high-temperature application.

In yet further specific experiments consistent with the above-noted one or more of these experiments, a dielectric film or layer, having a thickness in a range from 1 nanometer (nm) to 60 nm), is used between the GaN-based layer and the diamond layer section.

Certain experimental efforts and results are associated with a more detailed embodiment and an effective demonstration of H-terminated single crystal diamond hole-channel MESFET with a hole current density of ˜40 mA/mm. With a high breakdown field (10 MV/cm) and high carrier velocity (1.1×10⁷ cm/sec), diamond is a strong contender to perform as high power-high frequency devices. Diamond also presents a unique property of surface conduction through a hole-accumulation layer created by hydrogen termination. The hole-accumulation layer on the diamond surface is generally achieved by hydrogen plasma treatment of a CVD grown diamond layer on a single crystal diamond. However, this method may need or benefit from a diamond reactor chamber and hydrogen plasma capabilities. In connection with this disclosure, H-termination may be achieved on a Type IIa <100> single crystal diamond substrate using a simple glass tube furnace backfilled with pure hydrogen gas at high temperature of ˜850° C. Although Au contacts to hole-accumulation layer on CVD grown diamond layer has been successfully reported, it has been discovered that the adhesion of Au contacts to the single crystal diamond was poor exhibiting inconsistent contact properties. An optimized Pd contact exhibited better adhesion to single crystal H-terminated diamond surface offering low specific contact resistance (6.24 μΩ·cm), short transfer length (0.12 μm) and low contact resistivity (0.124 μΩ·cm²). Hole mobility of 29.5 cm²/V·s at a density of 6×10¹²/cm² was obtained in the channel from Hall measurements. Using the 850° C. hydrogen termination process associated with this disclosure along with Pd-based contacts, successful fabrication and characterization has been hereby realized for H-terminated single crystal diamond MESFETs with a gate length of LG=2 μm. A Pd/Au (120 nm-50 nm) metal stack was deposited as source and drain contacts and an Al/Au (100 nm-50 nm) metal stack as a Schottky gate contact. A maximum current density of 37.2 mA/mm was obtained at VGS=−8 V. A minimum subthreshold slope SS of 586 mV/dec and a transconductance gₘ of 5.2 mS/mm was obtained. The breakdown voltage was around −121 V in a device with gate to drain separation of 10 μm without any field plating and passivation. This is the first demonstration of diamond FET presenting around 40 mA/mm hole current density obtained without a CVD grown diamond layer.

Also, according to the present disclosure, using such manufacture-related methodology, various semiconductor structures and/or devices may be characterized as including a GaN-based layer that does not manifest etching damage, and/or a diamond layer that may be beneficial for spreading heat generated.

Various experimental examples, some of which are discussed hereinbelow, have demonstrated that the above-characterized aspects, structures and methodologies may be used in one or more semiconductive devices to form semiconductor circuits and devices including but not limited to one or a combination of semiconductor structures such as inverters of one or more types including, as examples, HEMT, MESFET, CFET, and/or CMOS, etc., involving high-level power/speed attributes and/or applications.

Before turning to the drawing to be discussed in detail below, it is noted that each of the above (briefly-described) examples are presented in part to illustrate aspects of the present disclosure, as might be recognized by the foregoing discussion. As further examples, such aspects may include: providing a protection layer on the surface region of the GaN-based layer. This material-based protection layer may be between the GaN-based layer and the PCD particles. This layer may mitigate damage to the GaN-based layer that may occur during processing steps involved with forming the semi-conductive structure.

Other certain exemplary aspects of the present disclosure involve methodology and structures directed to a semi-conductive structure a GaN-based layer that includes GaN in at least a surface region of the GaN-based layer. Also, a diamond layer section may be integrated on, or against, the surface region of the GaN-based layer. This diamond layer may be formed, for example, by growth via seeding the surface with PCD particles.

In more specific example, embodiments are directed to a semi-conductor structure having a GaN-based layer that does not manifest etching damage.

In yet another specific example, embodiments are directed to a semi-conductor structure having a diamond layer section. This diamond layer may have been grown by seeding with PCD particles. In this structure, the GaN-based layer may not manifest damage due to etching the grow layer of the diamond section, nor may it manifest damage due to properties of 2-dimensional electron gas (2DEG) manifesting during operation.

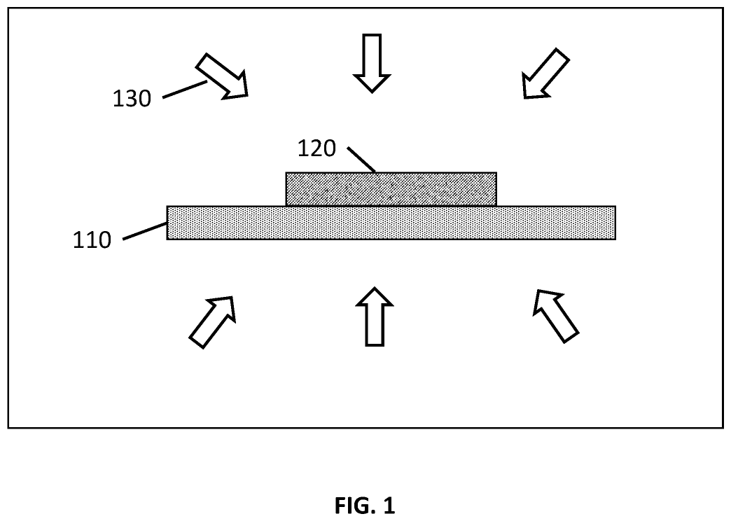

Turning to the drawings, FIG. 1 is a diagram illustrating seeding and growing PCD particles on a GaN-based layer while under pressure. The GaN-based layer 110 is seeded with PCD particles which may be grown under a selected pressure 130 to form a diamond layer section 120. This provides a semi-conductive structure that includes the diamond layer section 120 integrated on, or against, the surface region of the GaN-based layer 110.

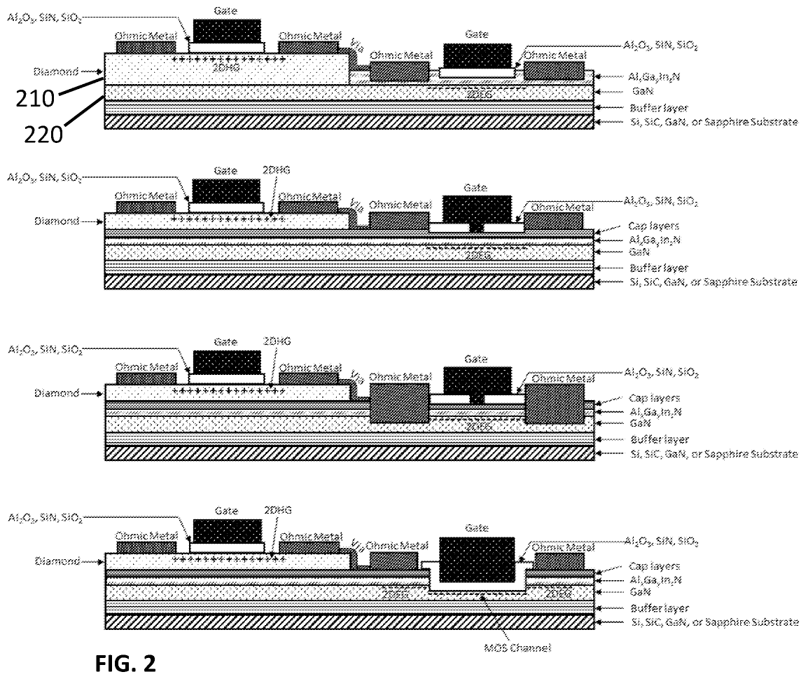

FIG. 2 is a cross section diagrams of a semi-conductive diamond-on-GaN constructed architecture involving HEMT structures. The lateral GaN High-Electron-Mobility Transistor (HEMT), also known as Heterojunction FET (or HFET), has shown superior performance in comparison with Si devices. High efficiency and/or high power density output from GaN HEMTs have been demonstrated for multiple applications. GaN HEMTs take the advantage of its high mobility 2-dimensional electron gas (2DEG) at the interface of AlGaN/GaN, where electrons move freely in a quantum well due to the presence of polarization charge. On the other hand, diamond exhibits the highest breakdown field (e.g., 10 MV/cm), has the largest thermal conductivity (>20 W/cm·K) of any of the wide-bandgap materials with a bandgap of about 5.45 eV, and can provide a high density 2-dimensional hole gas (2DHG) at the surface. Therefore, 2DHG from a hydrogen terminated diamond (hole-FET) can make a complementary logic with 2DEG from AlGaN/GaN HEMT. As illustrated, diamond 210 is integrated on top of a GaN HEMT structure 220 on a same substrate to provide the 2DHG.

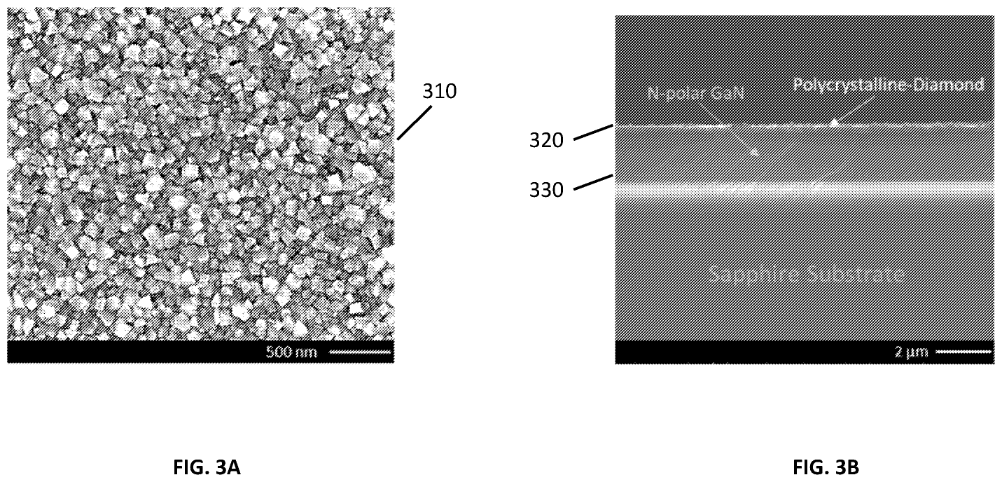

The top and cross-sectional view SEM micrographs of polycrystalline diamond-on-GaN are shown in FIG. 3A and FIG. 3B respectively. Diamond growth (310 and 320) may be done in a MPCVD (microwave plasma chemical vapor deposition) system, under a mixture of H₂ and CH₄ at around 650° C. As hydrogen plasma is the main species in diamond growth, it can damage the GaN layer 330 and change the properties of the 2-dimensional electron gas (2DEG). To overcome this issue, a polymer-assisted diamond nanoparticle seeding technique may be used prior to the growth, which works as the nucleation layer for diamond, and can protect the GaN 330 from extensive etching. The density of the nanoparticles after the seeding may be higher than 10¹² cm⁻², which provides a uniform and complete coverage of the surface. The other method that has been used is utilizing the protection layer (e.g., SiN on GaN) beside the seeding, to make sure no etching and good adhesion at the same time. For the growth part, a low power recipe (2% CH₄/H₂, ˜650° C., 40 Torr, 1300 W microwave plasma, 1 hour) may be used to deposit an UNCD (ultra-nano crystalline diamond) layer for better contact to GaN 330, and then the temperature may be elevated (by microwave power or pressure) to increase the size of the grains.

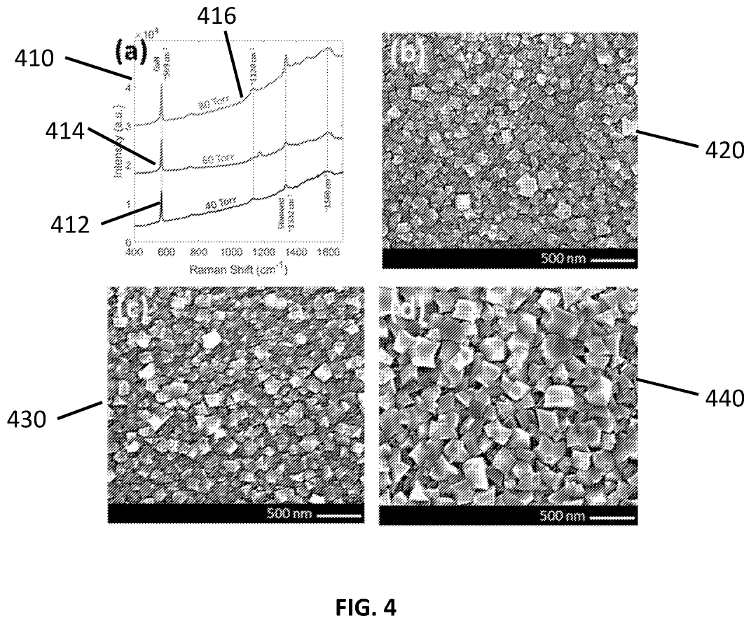

FIG. 4 is a Raman spectra graph 410 and top view micrographs (420, 430, 440) illustrating diamond-on-GaN growth at various pressures. Diamond-on-GaN growth using 40 torr pressure is shown in 420 while its corresponding Raman spectra graph is illustrated as 412. Diamond-on-GaN growth using 60 torr pressure is shown in 430 while its corresponding Raman spectra graph is illustrated as 414. Diamond-on-GaN growth using 80 torr pressure is shown in 440 while its corresponding Raman spectra graph is illustrated as 416.

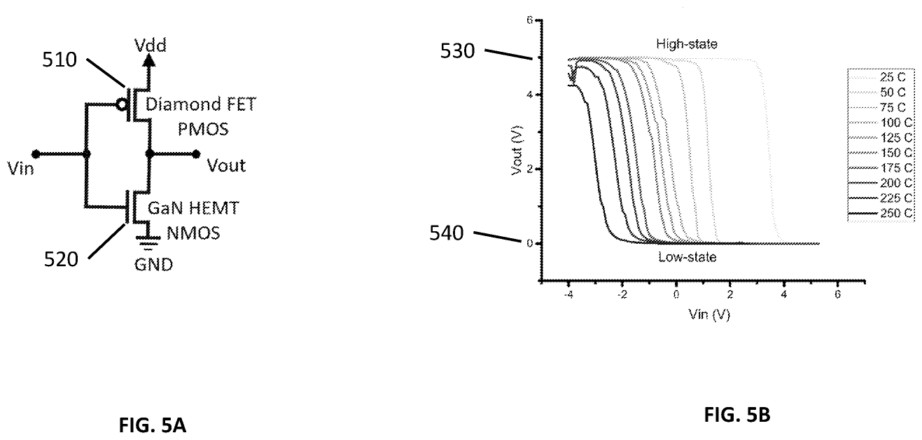

FIG. 5A illustrates a (Complementary Transistor) CMI/OS inverter constructed with a Diamond-on-GaN architecture. Lack of high temperature (>150° C.) performance places a limit on silicon CMOS technology for modern applications. Wide-bandgap semiconductors, GaN and diamond, provide a more reliable solution for operation at higher temperatures. High temperature (up to 250° C.) voltage transfer characteristics of a “CMOS-like” inverter including a diamond Hole-FET as PMOS 510 and an AlGaN/GaN HEMT as NMOS 520 is shown in FIG. 5B. The PMOS 510 is fabricated from single crystal diamond with a 2DHG as conductive channel achieved by Hydrogen Plasma treatment at ˜800° C. FIG. 5B shows that the complementary transistors completely reaches high-state 530 (Vdd=+5 V) and low-state 540 (GND=0 V) with only 1 V on-off transition voltage. This performance may prove excellent potential in even higher operation temperature (˜350 C) in the future.

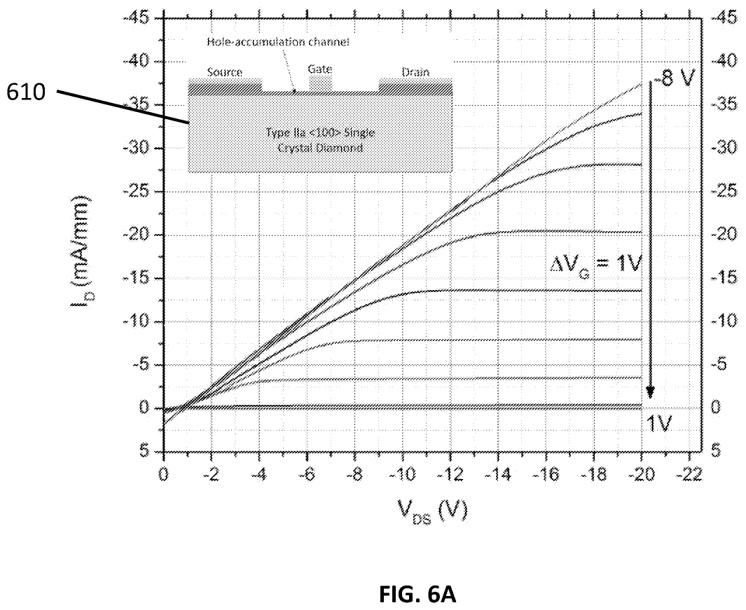

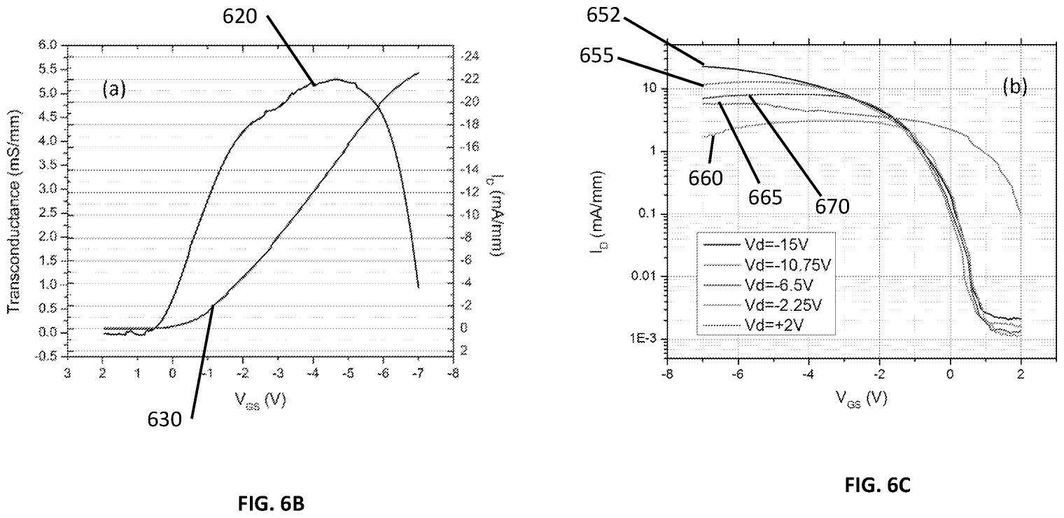

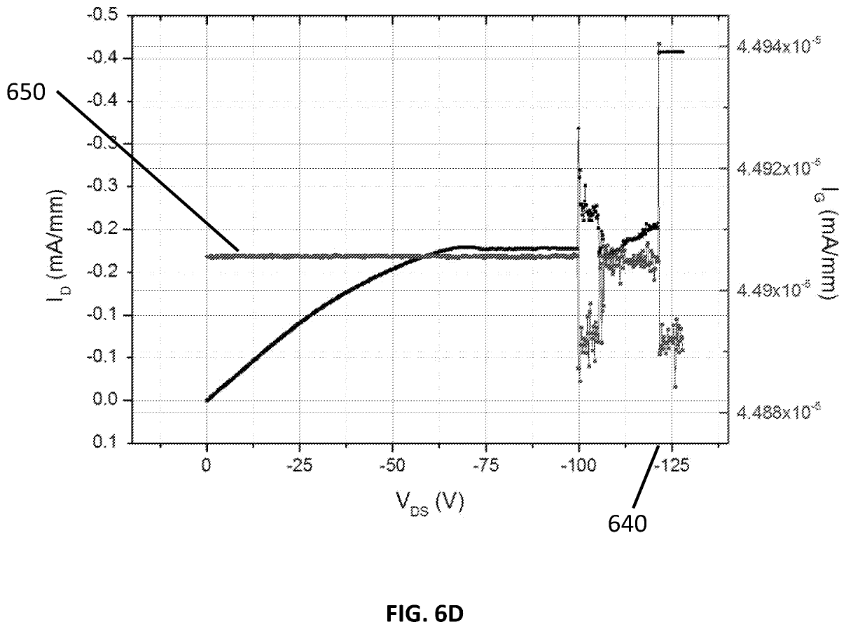

FIG. 6A is a graph illustrating the I_{D} versus V_{DS} characteristics of a MESFET constructed with a Diamond-on-GaN architecture. Typically, the diamond surface is oxygen-terminated after the growth. The 2D-hole gas formation enables the introduction of high-density holes without doping the material with hole mobility up to 200 cm²/Vs. The results of a “HoleFETs” on single-crystalline diamond. Hole [Hall] mobility of 60 cm²/V·s was measured and total current density of 40 mA/mm was recorded in the transistor with subthreshold slope of 586 mV/decade and a transconductance of 5.2 mS/mm ID-VDS characteristics of the MESFET for VG varying from 1V to −8V with ΔVG=1V. A maximum current density of 37.2 mA/mm is obtained at VG=−8V for a VDS at −20V. Inset 610 illustrates H-terminated hole-accumulation-layer channel MESFET with Pd/Au source-drain and Al/Au gate, LG=2 μm.

Continuing with the above discussion, the graphed aspects of FIG. 6B illustrate the gate bias dependent transconductance is depicted as 620 with a maximum value of 5.2 mS/mm. A plot showing I_{D} versus V_{GS} is depicted as 630.

In FIG. 6C, the graphed aspects illustrate graph the ID-VGS characteristics of the MESFET for different VD varying from 2V to −15V. A typical subthreshold slope of 586 mV/dec is extracted from a linear fitting of the ID-VGS data and ID are shown for VDS=−15 V as at plot 652. Similarly, the other plots respectively correspond to VDS=−10.75 V at plot 655, VDS=−2.25 V at plot 660, VDS=+2 V at plot 665, and VDS=−6.5 V at plot 670.

Again, continuing with the above discussion, the graph of FIG. 6D illustrates the breakdown voltage 640 V_{BR}=−121 V is obtained to give a breakdown field of −121 kV/cm. A low I_{G} 650 value is maintained at 4.49×10⁻⁸ mA/mm.

Accordingly, many different types of processes and devices using seeding of GaN-based layer with polycrystalline diamond (PCD) particles may be advantaged by such aspects, the above aspects and examples as well as others (including the related examples in the above-identified U.S. Provisional application (STFD.411P1) which includes, for example, supporting data as discussed hereinabove for the disclosed experimental efforts and results).

It is recognized and appreciated that as specific examples, the above-characterized figures and discussion are provided to help illustrate certain aspects (and advantages in some instances) which may be used in the manufacture of such structures and devices. These structures and devices include the exemplary structures and devices described in connection with each of the figures as well as other devices, as each such described embodiment has one or more related aspects which may be modified and/or combined with the other such devices and examples as described hereinabove may also be found in the Appendices of the above-referenced Provisionals.

The skilled artisan would also recognize various terminology as used in the present disclosure by way of their plain meaning. As examples, the Specification may describe and/or illustrates aspects useful for implementing the examples by way of various semiconductor materials/circuits which may be illustrated as or using terms such as layers, certain material-based layers, blocks, modules, device, system, unit, controller, and/or other circuit-type or material-type depictions. In connection with such descriptions unless otherwise indicated, the term “[ ]-based layer”, “[ ]-based structure”, etc., may refer to such layer or structure which entirely or predominantly include the chemistry immediately preceding “-based”, and the term “source” may refer to source and/or drain interchangeably in the case of a transistor structure. Such semiconductor and/or semiconductive materials (including portions of semiconductor structure) and circuit elements and/or related circuitry may be used together with other elements to exemplify how certain examples may be carried out in the form or structures, steps, functions, operations, activities, etc. It would also be appreciated that terms to exemplify orientation, such as upper/lower, left/right, top/bottom and above/below, may be used herein to refer to relative positions of elements as shown in the figures. It should be understood that the terminology is used for notational convenience only and that in actual use the disclosed structures may be oriented different from the orientation shown in the figures. Thus, the terms should not be construed in a limiting manner.

Based upon the above discussion and illustrations, those skilled in the art will readily recognize that various modifications and changes may be made to the various embodiments without strictly following the exemplary embodiments and applications illustrated and described herein. For example, methods as exemplified in the Figures may involve steps carried out in various orders, with one or more aspects of the embodiments herein retained, or may involve fewer or more steps. Such modifications do not depart from the true spirit and scope of various aspects of the disclosure, including aspects set forth in the claims.

What is claimed:

1. A method comprising:
forming a GaN-based layer characterized as including GaN in at least a surface region of the GaN-based layer via monolithically integrating or seeding by use of polycrystalline diamond (PCD) particles on the GaN-based layer characterized as including GaN in at least a surface region of the GaN-based layer; and
growing the PCD particles under a selected pressure to form a diamond layer section to provide a semi-conductive structure that includes the diamond layer section integrated on or against the surface region of the GaN-based layer.

2. The method of claim 1, wherein the pressure is selected to set a grain size, associated with sp² and hydrogen content in the diamond layer section, and the step of growing the PCD particles under a selected pressure follows the step of forming with PCD particles.

3. The method of claim 1, wherein the step of forming includes said seeding by use of PCD particles on the GaN-based layer, and the step of growing the PCD particles under a selected pressure to form a diamond layer section may be achieved with or without use of chemical vapor deposition (CVD).

4. The method of claim 1, wherein the semi-conductive structure includes or is a GaN-based FET and includes the diamond layer section, integrated on or against the surface region of the GaN-based layer, for spreading heat while the GaN-based FET is being operated.

5. The method of claim 1, further including oxygen-terminating a surface of the diamond layer section after said step of growing.

6. The method of claim 1, wherein the semi-conductive structure includes or is a crystal-diamond-based MESFET.

7. The method of claim 1, wherein the semi-conductive structure includes or is a GaN-based HEMT.

8. The method of claim 1, wherein said forming with polycrystalline diamond (PCD) particles provides an activation region for said growing the PCD particles.

9. The method of claim 1, further including etching wherein said forming with polycrystalline diamond (PCD) particles provides etching protection to the GaN-based layer.

10. The method of claim 1, wherein said forming includes seeding by locating the polycrystalline diamond (PCD) particles directly on the surface region of the GaN-based layer.

11. The method of claim 1, further including providing a protection layer on the surface region of the GaN-based layer, the material-based protection layer being between the GaN-based layer and the polycrystalline diamond (PCD) particles, wherein material-based protection layer is characterized as mitigating damage to the GaN-based layer during further processing steps involved with forming the semi-conductive structure.

12. The method of claim 1, wherein the polycrystalline diamond (PCD) particles are characterized as having a grain size that is within a range from 650 nanometers to 2.5 microns.

13. The method of claim 1, wherein the polycrystalline diamond (PCD) particles are characterized as having a grain size that is within a range from 650 nanometers to several microns, whereby said growing facilitates the monolithic integration of the semi-conductive structure and a structure including the GaN-based layer.

14. The method of claim 1, wherein the polycrystalline diamond (PCD) particles are characterized as having a grain size that is within a range from 650 nanometers to several microns, and further including controlling growth parameters during said growing, wherein said growth parameters controlled during said growth include: pressure, temperature, cooling.

15. The method of claim 1, further including using a dielectric film or layer, having a thickness in a range from 1 nanometer (nm) to 60 nm), between the GaN-based layer and the diamond layer section.

16. The method of claim 1, wherein said forming a GaN-based layer includes the step of seeding with polycrystalline diamond (PCD) particles on the GaN-based layer.

17. The method of claim 1, further including a thermo-based pressure step applied to single crystalline diamond.

18. A semi-conductive structure comprising:
a GaN-based layer characterized as including GaN in at least a surface region of the GaN-based layer; and
a diamond layer section, integrated on or against the surface region of the GaN-based layer, and characterized as having been formed by monolithic integration with polycrystalline diamond (PCD) particles.

19. The semi-conductive structure of claim 18, wherein the GaN-based layer does not manifest etching damage.

20. The semi-conductive structure of claim 18, wherein the diamond layer section is characterized as having been formed via monolithic integration with polycrystalline diamond (PCD) particles as apparent from the GaN-based layer not manifesting damage due to: etching, growth of the diamond layer section; and/or properties of a 2-dimensional electron gas (2DEG) manifesting during operation.
